(19) United States
(12) Patent Application Publication
(10) Pub. No.: US 2025/0096155 A1
(43) Pub. Date: Mar. 20, 2025

(54) SEMICONDUCTOR DEVICE AND METHOD FOR FORMING THE SAME

(71) Applicant: Taiwan Semiconductor Manufacturing Company, Ltd., Hsinchu (TW)

(72) Inventors: Wen-Chieh LO, Hsinchu City (TW); Wei-Tse HSU, Zhubei City (TW); Ya-Ching TSENG, Hsinchu City (TW); Yung-Shih CHENG, Hsinchu City (TW)

(73) Assignee: Taiwan Semiconductor Manufacturing Company, Ltd., Hsinchu (TW)

(21) Appl. No.: 18/469,410

(22) Filed: Sep. 18, 2023

(51) Int. Cl. H01L 23/00; H01L 21/3105; H01L 21/56; H01L 21/768; H01L 23/528

(52) U.S. Cl. CPC H01L 23/562; H01L 21/31053; H01L 21/56; H01L 21/768; H01L 23/528

(57) ABSTRACT

A method for forming a semiconductor device is provided. The method includes forming a device layer over a device substrate and forming a front-side interconnect structure over the device layer. The method also includes forming a bevel oxide over an edge portion of the device substrate, an edge portion of the device layer, and an edge portion of the front-side interconnect structure. The method further includes forming an oxide layer over the device layer, the front-side interconnect structure, and the bevel oxide, polishing the bevel oxide and the oxide layer until a top surface of the bevel oxide is substantially level with a top surface of the oxide layer, and attaching a carrier substrate to the bevel oxide and the oxide layer.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three dimensional integrated circuits (3DICs) are a recent development in semiconductor packaging in which multiple semiconductor dies are stacked upon one another, such as package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, as examples. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a device substrate and a device layer formed thereon in accordance with some embodiments.

FIG. 2A to FIG. 2J illustrate cross-sectional views of forming a semiconductor device in accordance with some embodiments.

FIG. 3A to FIG. 3D illustrate cross-sectional views of forming an intermediate structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, or the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Typically, a semiconductor device has a central region and a bevel region close to its edge. Bevel defects such as peeling (also known as delamination) or deformation may occur in the bevel region because of the curved edge. To eliminate the bevel defects, a bevel oxide is deposited in the bevel region. However, in current manufacturing processes, when attaching a carrier substrate to the semiconductor device, direct bonding between the carrier substrate and the bevel oxide is not preferred. In particular, in current manufacturing processes, a bonding layer that can be wrapped around the bevel oxide and that provides bonding with the carrier substrate is needed. What is needed, therefore, is a combination of manufacturing processes for forming the bonding layer (such as a deposition process and a planarization process). The bonding layer that wraps the bevel oxide may increase the overall thickness of the semiconductor device and manufacturing costs. Some embodiments of the present disclosure provide direct bonding between the carrier substrate and the bevel oxide, which may reduce the thickness of the semiconductor device and simplify the manufacturing processes.

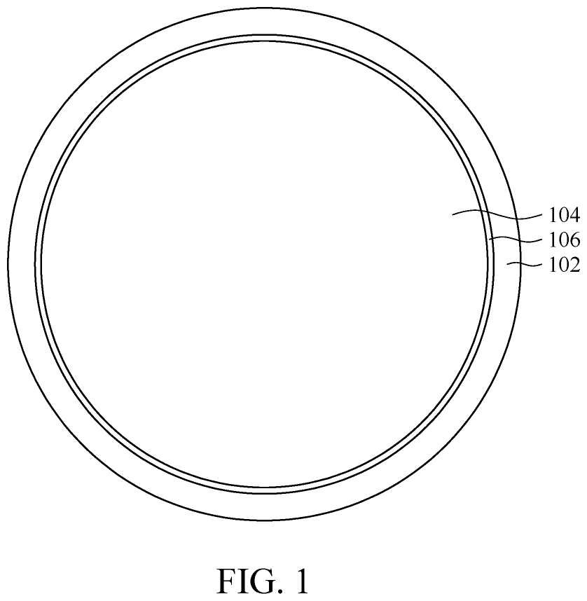

FIG. 1 illustrates a top view of a device substrate 102 and a device layer 104 formed thereon in accordance with some embodiments. The device substrate 102 may be a semiconductor wafer, such as a silicon wafer. Alternatively or additionally, the device substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP. The device substrate 102 may include a central region and a bevel region that is closer to its edge. The device layer 104 may include various layers formed by various manufacturing processes, e.g., front end-of-line (FEOL) processes. During these manufacturing processes, a device recessed portion 106 may be inevitably formed in the bevel region of the device substrate 102.

The device layer 104 may include various device components/features, such as doped wells (e.g., n-wells and/or p-wells), isolation features (e.g., shallow trench isolation (STI) structures and/or other suitable isolation structures), gates (e.g., a gate stack having a gate electrode and a gate dielectric), gate spacers along sidewalls of the gates, source/drains (e.g., epitaxial source/drains), other suitable device components and/or device features, or a combination thereof.

In some embodiments, the device layer 104 include a planar transistor, where a channel of the planar transistor is formed in the semiconductor substrate between respective source/drains and a respective gate is disposed on the channel (e.g., on a portion of the semiconductor substrate in which the channel is formed). In some embodiments, the device layer 104 include a non-planar transistor having a channel formed in a semiconductor fin that extends from the semiconductor substrate and between respective source/drains on/in the semiconductor fin, where a respective gate is disposed on and wraps the channel of the semiconductor fin (i.e., the non-planar transistor is a fin-like field effect transistor (FinFET)). In some embodiments, the device layer 104 include a non-planar transistor having channels formed in semiconductor layers suspended over the device substrate 102 and extending between respective source/drains, where a respective gate is disposed on and at least partially surrounds the channels (i.e., the non-planar transistor is a gate-all-around (GAA) transistor and/or a fork-sheet transistor). The various transistors can be configured as planar transistors or non-planar transistors depending on design requirements.

The device substrate 102 and/or the device layer 104 may include various passive electronic devices and active electronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or a combination thereof. The various electronic devices can be configured to provide functionally distinct regions of an IC, such as a logic region (i.e., a core region), a memory region, an analog region, a peripheral region (e.g., an input/output (I/O) region), a dummy region, other suitable region, or a combination thereof. The logic region may be configured with standard cells, each of which can provide a logic device and/or a logic function, such as an inverter, an AND gate, an NAND gate, an OR gate, an NOR gate, a NOT gate, an XOR gate, an XNOR gate, other suitable logic device, or a combination thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or a combination thereof. In some embodiments, memory cells and/or logic cells include transistors and interconnect structures that combine to provide storage devices/functions and logic devices/functions, respectively, of a chip.

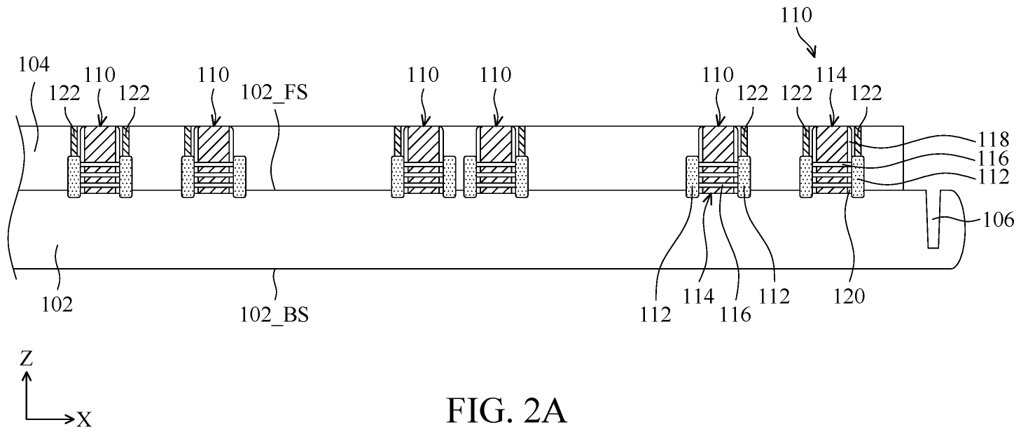

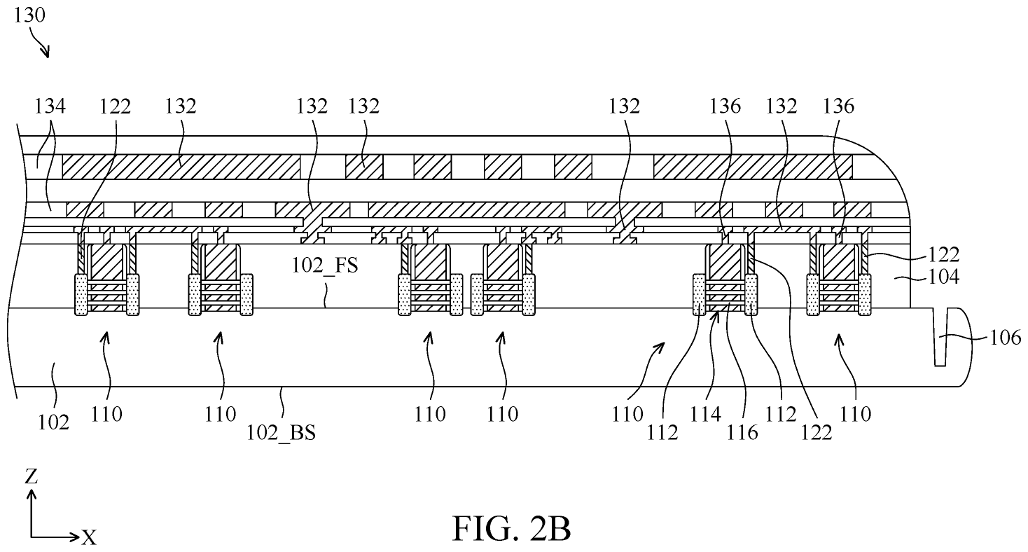

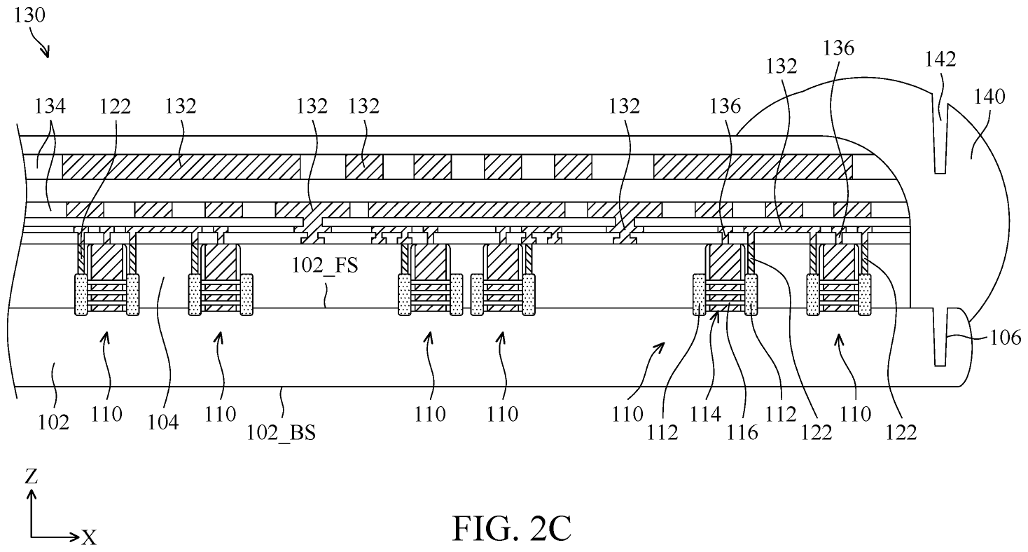

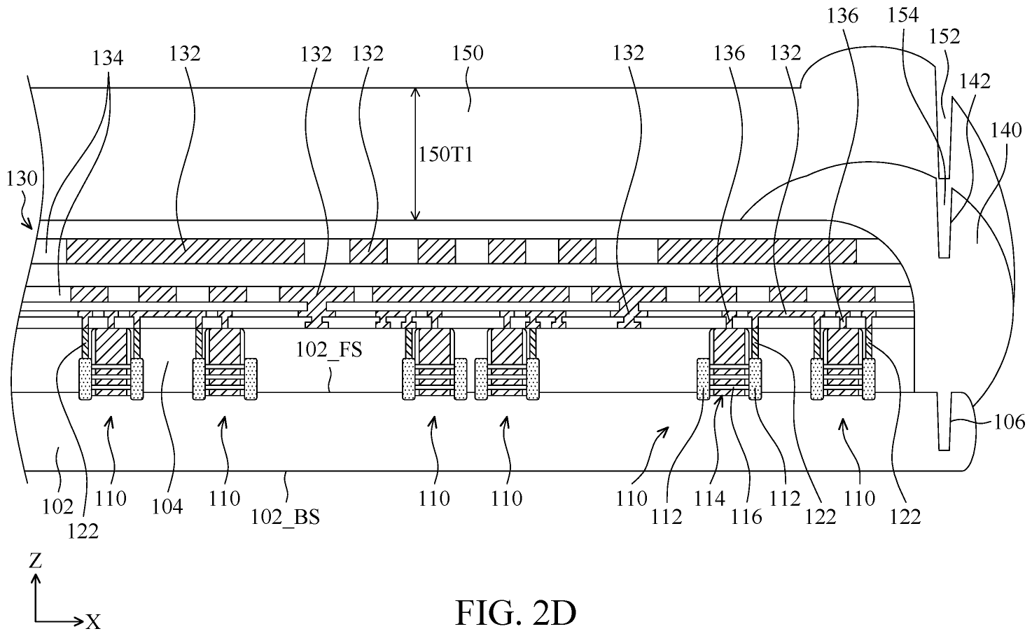

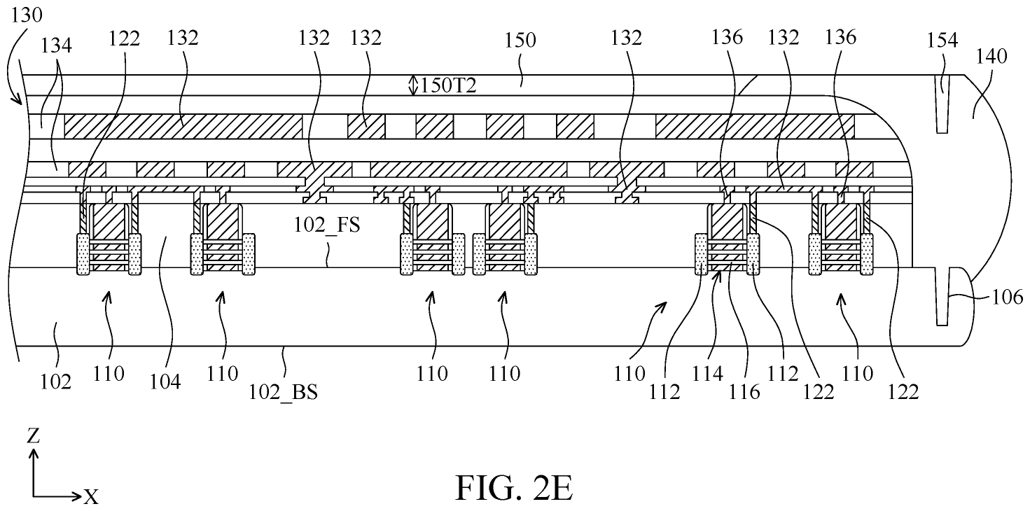

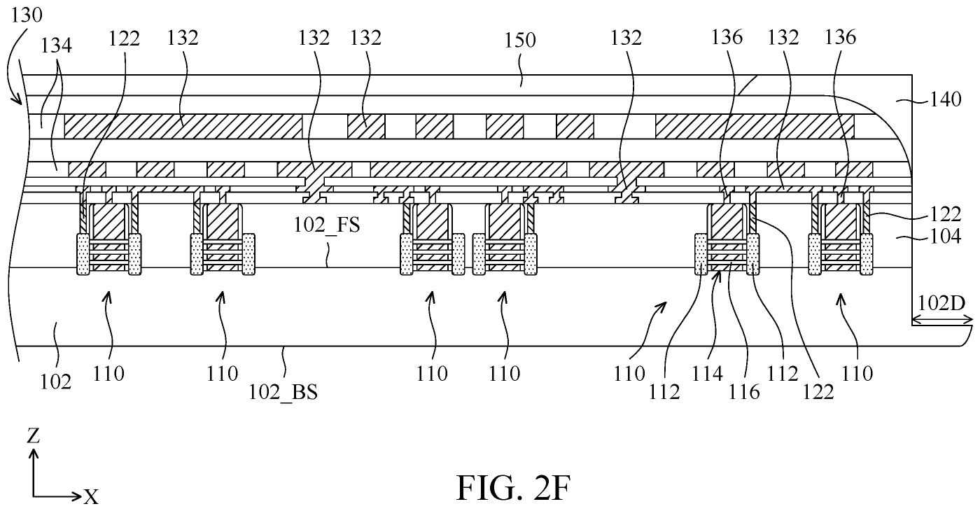

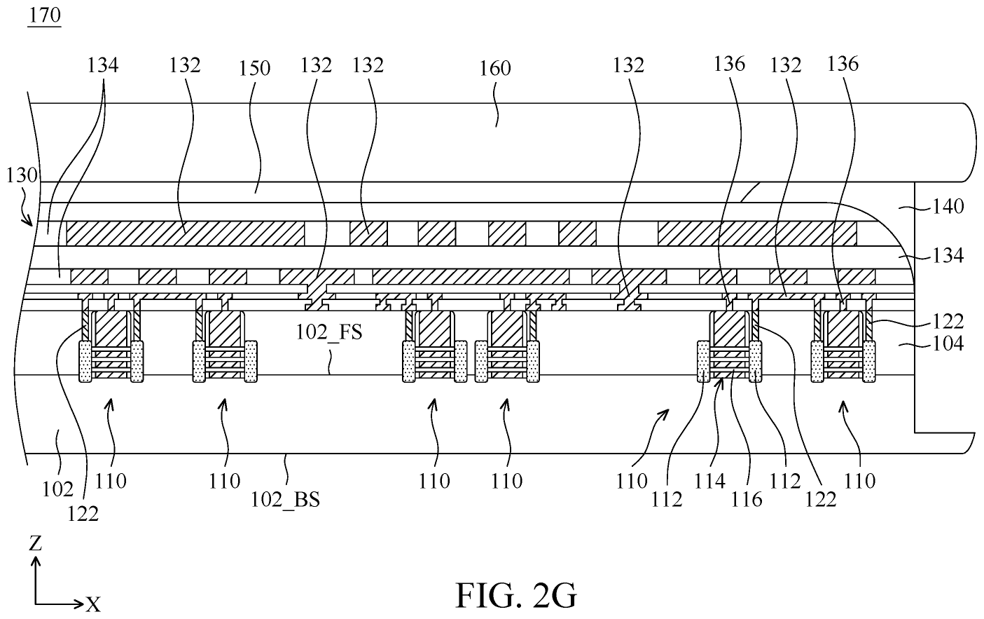

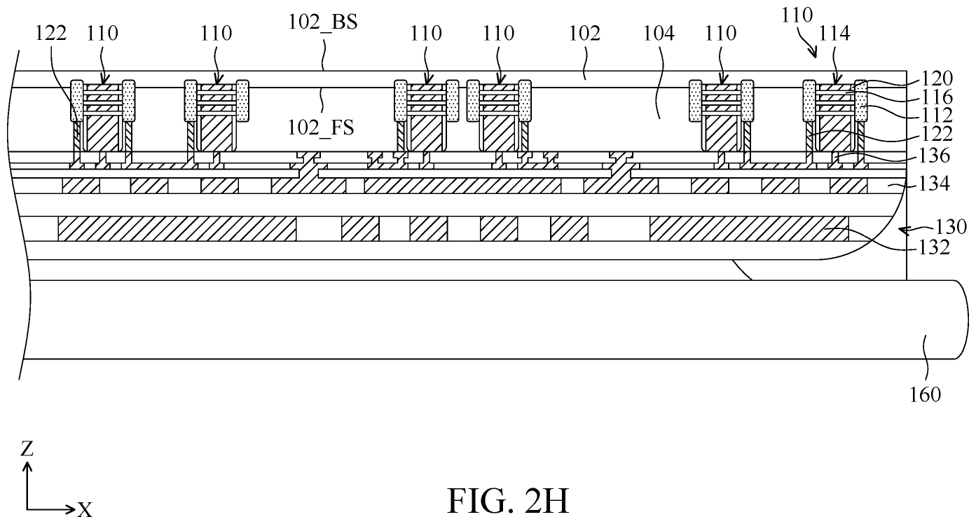

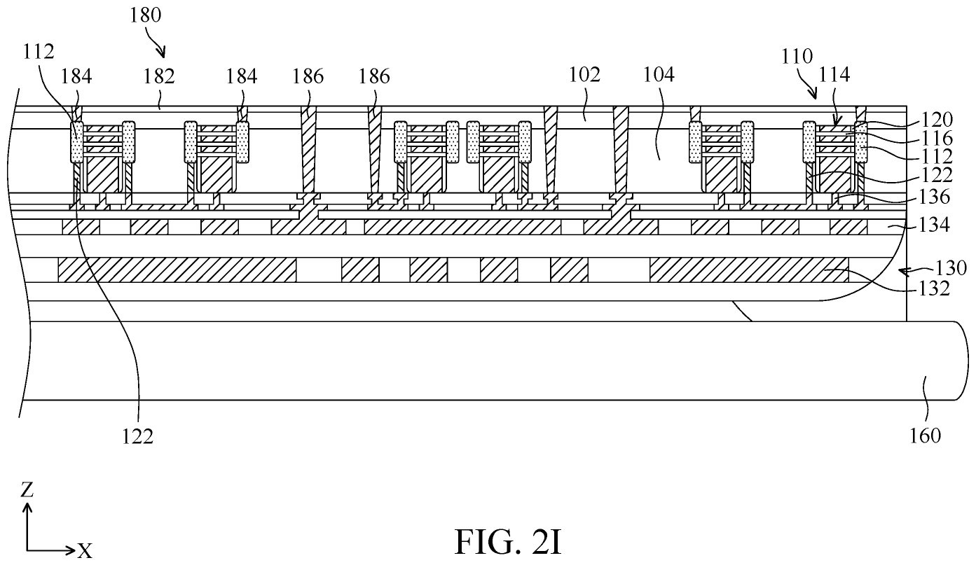

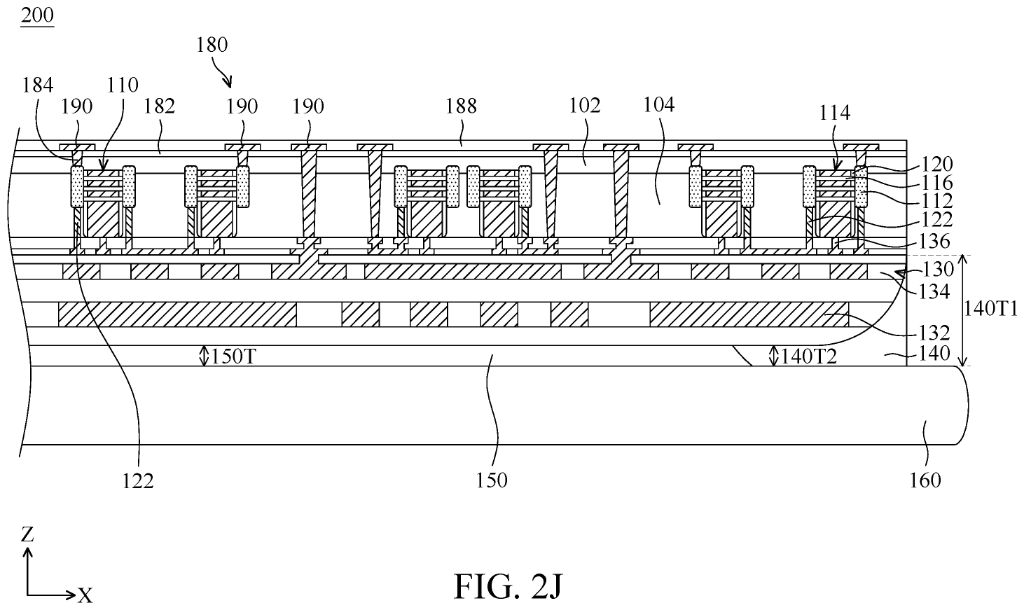

FIG. 2A to FIG. 2J illustrate cross-sectional views of forming a semiconductor device 200 in accordance with some embodiments. Please refer to FIG. 2A. The device substrate 102 may have a front-side 102_FS and a back-side 102_BS that is opposite to the front-side 102_FS. The device layer 104 is formed over the front-side 102_FS of the device substrate 102. The device layer 104 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The device layer 104 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

The device layer 104 may include a plurality of electrical devices 110 formed therein. In other words, the electrical devices 110 may be formed over the front-side surface 102_FS of the device substrate 102. Each electrical device 110 may be a transistor, such as a nanostructure transistor (e.g., a nanosheet transistor, a nanowire transistor, a multi-bridge channel transistor, a nano-ribbon FET, or a gate all around (GAA) transistor). Each electrical device 110 may include a plurality of source/drain structures 112, a plurality of gate structures 114, a plurality of channel layers 116, a plurality of gate spacers 118, and a plurality of inner spacers 120.

The source/drain structures 112 are attached to the opposite sides of the channel layers 116 in the X-direction. The source/drain structures 112 may refer to a source or a drain, individually or collectively, depending upon the context. The gate structures 114 wrap around the channel layers 116 and extend along the Y-direction. The channel layers 116 are suspended over the device substrate 102 in the Z-direction. In some embodiments, the gate spacers 118 and the inner spacers 120 are formed from a spacer layer. The spacer layer may include one or more dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The spacer layer may be etched to form the gate spacers 118 and the inner spacers 120.

In some embodiments, a dummy gate structure may be formed across a plurality of fin structure to define the channel regions of the resulting transistors (e.g., the electrical devices 110). The gate spacers 118 may be configured to separate source/drain structures 112 from the dummy gate structure. The inner spacers 120 may be configured to separate the source/drain structures 112 and the gate structures 114.

In addition, a plurality of source/drain contacts 122 may be formed in the device layer 104. The source/drain contacts 122 are connected to the source/drain structures 112 of the electrical device 110. In some embodiments, the source/drain contacts 122 may be made of a conductive material including aluminum (Al), copper (Cu), tungsten (W), titanium (Ti), tantalum (Ta), titanium nitride (TiN), cobalt, tantalum nitride (TaN), nickel silicide (NiSi), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The source/drain contacts 122 may further include a liner and/or a barrier layer. For example, a liner (not shown) may be formed on the sidewalls and bottom of the contact trench. The liner may be made of silicon nitride, although any other applicable dielectric may be used as an alternative. The liner may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes. The barrier layer may be made of tantalum nitride, although other materials, such as tantalum, titanium, titanium nitride, or the like, may also be used.

After the electrical devices 110 are formed, a front-side interconnect structure 130 is formed over the device layer 104, as shown in FIG. 2B in accordance with some embodiments. In particular, the front-side interconnect structure 130 is formed over the front-side surface of the electrical devices 110, and the device substrate 102 is located on the back-side surface of the electrical devices 110. In some embodiments, the width of the top surface of the front-side interconnect structure 130 is different from the width of the bottom surface of the front-side interconnect structure 130 because the edges of the front-side interconnect structure 130 are affected by the bevel region of the device substrate 102 during the manufacturing processes. The front-side interconnect structure 130 may be formed by a damascene process, such as a single damascene process, a dual damascene process, combinations thereof, or the like. In some embodiments, the front-side interconnect structure 130 includes a plurality of conductive structures 132 (e.g., vias and metal lines) formed in a plurality of dielectric layers 134. In some embodiments, the conductive structures 132 are electrically connected to the source/drain contacts 122.

The dielectric layers 134 may include dielectric materials, such as silicon oxide, silicon nitride, silicon oxynitride, phosphosilicate glass (PSG), borophosphosilicate glass (BPSG), and/or other applicable low-k dielectric materials. The dielectric layer 134 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

In some embodiments, the front-side interconnect structure 130 further includes a plurality of contact plugs 136 landing on the gate structures 114 and electrically connected to the gate structures 114. In some embodiments, the conductive structures 132 and the contact plugs 136 are made of a conductive material including aluminum (Al), copper (Cu), tungsten (W), titanium (Ti), tantalum (Ta), titanium nitride (TiN), cobalt, tantalum nitride (TaN), nickel silicide (NiSi), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the conductive structures 132 and the contact plugs 136 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

After the front-side interconnect structure 130 is formed, a bevel oxide 140 may be formed over the edge portion of the device substrate 102, the edge portion of the device layer 104, and the edge portion of the front-side interconnect structure 130, as shown in FIG. 2C in accordance with some embodiments. The bevel oxide 140 is mainly formed in the bevel region. In some embodiments, the bevel oxide 140 may include dielectric materials. In some embodiments, The bevel oxide 140 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

In some embodiments, the formation of the bevel oxide 140 includes filling the device recessed portion 106 of the device substrate 102 with the bevel oxide 140. The formation of the bevel oxide 140 is affected by the topography of the underlying structures, and thus a bevel oxide recessed portion 142 is formed in the bevel oxide 140. The bevel oxide recessed portion 142 at least partially overlaps the device recessed portion 106 vertically. In some embodiments, the thickness of the bevel oxide recessed portion 142 is different from the thickness of the device recessed portion 106.

After the bevel oxide 140 is formed, an oxide layer 150 may be formed over the device layer 104, the front-side interconnect structure 130, and the bevel oxide 140, as shown in FIG. 2D in accordance with some embodiments. In some embodiments, the oxide layer 150 includes silicon oxide, silicon nitride, silicon oxynitride, tetraethoxysilane (TEOS), TEOS formed oxide, or the like. In some embodiments, the oxide layer 150 and the bevel oxide 140 are made of different dielectric materials. The oxide layer 150 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

In some embodiments, the formation of the oxide layer 150 includes depositing the oxide layer 150 until the thickness 150T1 of the portion of the oxide layer 150 that is not over the bevel oxide 140 is about 1000 nm. In some embodiments, the formation of the oxide layer 150 includes filling the bevel oxide recessed portion 142 with the oxide layer 150. In other words, the oxide layer 150 includes an oxide layer extending portion 154 extending into the bevel oxide recessed portion 142. The formation of the oxide layer 150 is affected by the topography of the underlying structures, and thus an oxide layer recessed portion 152 in the oxide layer 150 is formed. The oxide layer recessed portion 152 at least partially overlaps the bevel oxide recessed portion 142 and the device recessed portion 106 vertically, and the bevel oxide recessed portion 142 is between the device recessed portion 106 and the oxide layer recessed portion 152.

After the oxide layer 150 is deposited to a predetermined thickness, the bevel oxide 140 and the oxide layer 150 may be partially removed until the top surface of the bevel oxide 140 is substantially level with the top surface of the oxide layer 150, as shown in FIG. 2E in accordance with some embodiments. The bevel oxide 140 and the oxide layer 150 may be partially removed using a planarization process such as chemical mechanical polishing (CMP) process or any other applicable planarization process. In some embodiments, the polishing rate of the oxide layer 150 is different from the polishing rate of the bevel oxide 140 during the CMP process.

The polishing of the bevel oxide 140 and the oxide layer 150 reduces the thickness of the bevel oxide 140 and the thickness of the oxide layer 150 along the Z-direction. In some embodiments, the polishing of the bevel oxide 140 includes exposing the oxide layer extending portion 154 of the oxide layer 150. In some embodiments, the polishing of the oxide layer 150 includes polishing the oxide layer 150 until the thickness 150T2 of the portion of the oxide layer 150 that is not over the bevel oxide 140 is in a range from about 200 nm to about 300 nm.

After the bevel oxide 140 and the oxide layer 150 are polished, the edge portion of the bevel oxide 140, the edge portion of the front-side interconnect structure 130, and the edge portion of the device substrate 102 are trimmed off, as shown in FIG. 2F in accordance with some embodiments. In some embodiments, the trim of the edge portion of the bevel oxide 140 includes removing the portion of the bevel oxide 140 where the bevel oxide recessed portion 142 is located. In some embodiments the width of the top surface of the device substrate 102 is less than the width of the bottom surface of the device substrate 102 after the trim of the bevel oxide 140, the front-side interconnect structure 130, and the device substrate 102. In some embodiments, the width 102D of the portion that is trimmed off (i.e., substantially the same as the difference between the width of the top surface of the device substrate 102 and the width of the bottom surface of the device substrate 102) is in a range from about 0.5 mm to about 5 mm.

Next, a carrier substrate 160 is attached to the bevel oxide 140 and the oxide layer 150 to form an intermediate structure 170, as shown in FIG. 2G in accordance with some embodiments. The attachment of the carrier substrate 160 may form covalent bonds between the carrier substrate 160 and the bevel oxide 140 and covalent bonds between the carrier substrate 160 and the oxide layer 150. In some embodiments, the bonding process may further include applying a surface treatment to one or more of the bevel oxide 140 and the oxide layer 150. For example, the surface treatment may include a plasma treatment performed in vacuum environment. After the plasma treatment, the surface treatment may further include a cleaning process (e.g., rinse with deionized water) applied to one or more of the bevel oxide 140 and the oxide layer 150. The carrier substrate 160 is then aligned with the device substrate 102, and the carrier substrate 160 is pressed to initiate a pre-bonding process. For example, a push pin may extend through a carrier substrate chuck (not specifically illustrated) to bend the central region of the carrier substrate 160. By bending the carrier substrate 160, physical contact is initially made in the central region of the carrier substrate 160. The carrier substrate chuck may then be moved further downward to bond a growing concentric circle until the bevel region of the carrier substrate 160 is bonded with the bevel oxide 140.

As a result, a bonded interface is formed between the carrier substrate 160 and bevel oxide 140 and the oxide layer 150. Therefore, the carrier substrate 160 may be bonded with the bevel oxide 140 and the oxide layer 150 together in a stable way, and the performance of the resulting semiconductor device 200 may be improved. Due to the trim off of the bevel oxide 140, the front-side interconnect structure 130, and the device substrate 102 before the attachment of the carrier substrate 160 to the bevel oxide 140 and the oxide layer 150, the possibility of fracture and breakage occurred in the intermediate structure 170 may be further reduced.

After the intermediate structure 170 is formed, the intermediate structure 170 is flipped over, and a thinning process is performed on the intermediate structure 170, as shown in FIG. 2H in accordance with some embodiments. In other words, the device substrate 102 is flipped over and thinned. The thinning process may be a grinding process, a planarization process (e.g., CMP), an etching process, other suitable process, or a combination thereof. The thinning process includes removing at least part of the device substrate 102, and the thinning process is applied to the back-side 102_BS of the device substrate 102. In some embodiments, a grinding process or CMP is performed to remove a majority of the device substrate 102 and then followed by a suitable etch-back process to remove either a remainder of the device substrate 102 or to form openings (not specifically illustrated) in the device substrate 102 to expose certain portions of the electrical devices 110 in the device layer 104.

Then, a back-side interconnect structure 180 is formed, as shown in FIG. 2I in accordance with some embodiments. The back-side interconnect structure 180 may be able to decouple I/O and power wiring by power rails on the back-side surface, addressing challenges like elevated via resistances in back-end-of-line (BEOL) processes. This may enhance performance of transistors and reduce power consumption. Also, power wiring on back-side surface eliminates some potential interference between data and power connections. In some embodiments, the back-side interconnect structure 180 includes a dielectric layer 182, a plurality of back-side vias 184, a plurality of back-side through vias 186.

In some embodiments, before forming the back-side vias 184, back-side vias trenches are formed through the dielectric layer 182 and the device substrate 102, so that the bottom portions of the source/drain structures 112 are exposed. In some embodiments, the bottom portions of the source/drain structures 112 are also slightly removed. Then, a plurality of back-side silicide layers (not shown) are formed over the exposed source/drain structures 112, and the back-side vias 184 are formed over the back-side silicide layers. In some embodiments, the back-side silicide layers are formed by forming metal layers over the exposed surfaces of the source/drain structures 112 and annealing the metal layers, so the metal layers react with the source/drain structures 112 to form the back-side silicide layers. The unreacted metal layers are removed after the back-side silicide layers are formed in accordance with some embodiments. In some embodiments, the back-side silicide layers are N-type epi silicide such as TiSi, CrSi, TaSi, MoSi, ZrSi, HfSi, ScSi, Ysi, HoSi, TbSI, GdSi, LuSi, DySi, ErSi, YbSi, or the like. In some embodiments, the back-side silicide layers are P-type epi silicide such as NiSi, CoSi, MnSi, Wsi, FeSi, RhSi, PdSi, RuSi, PtSi, IrSi, OsSi, or the like. After the back-side silicide layers are formed, a conductive filling layer is formed to fill the back-side via trenches, and a polishing process is performed to form the back-side vias 184.

In some embodiments, the back-side through vias 186 are formed through the dielectric layer 182, the device substrate 102, and the device layer 104. In addition, the back-side through vias 186 are electrically connected to the conductive structures 132 in the front-side interconnect structure 130. In some embodiments, the back-side vias 184 and the back-side through vias 186 are made of a conductive material including aluminum (Al), copper (Cu), tungsten (W), titanium (Ti), tantalum (Ta), titanium nitride (TiN), cobalt, tantalum nitride (TaN), nickel silicide (NiSi), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. The back-side vias 184 and the back-side through vias 186 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

A liner layer (not shown) and/or a barrier layer (not shown) may be formed on the sidewalls of the back-side vias 184 and the back-side through vias 186. For example, the liner layer may include silicon nitride, although any other applicable dielectric may be used as an alternative. For example, the barrier layer may include tantalum nitride, although other materials, such as tantalum, titanium, titanium nitride, or the like, may also be used. The liner layer and the barrier layers may be formed using a process such as chemical vapor deposition (CVD), physical vapor deposition (PVD), plasma enhanced CVD (PECVD), plasma enhanced physical vapor deposition (PEPVD), atomic layer deposition (ALD), or another applicable processes. In some embodiments, each of the back-side vias 184 and the back-side through vias 186 has a width in a range from about 15 nm to about 30 nm in the X-direction. In some embodiments, each of the back-side vias 184 and the back-side through vias 186 has a width in a range from about 15 nm to about 30 nm in the Y-direction. In some other embodiments, the device substrate 102 is completely removed after the back-side vias 184 and the back-side through vias 186 are formed.

The back-side interconnect structure 180 may further include a dielectric layer 188 and a plurality of back-side metal pads 190. The dielectric layer 188 is formed over the back-side surface of the electrical devices 110, and the back-side metal pads 190 are formed in the dielectric layer 188, as shown in FIG. 2J in accordance with some embodiments. In some embodiments, the back-side metal pads 190 are metal lines embedded in the dielectric layer 188. In some embodiments, the dielectric layer 188 includes multiple layers made of low k dielectric materials having a k value lower than 7. In some embodiments, the dielectric layer 188 is made of SiO₂, SiN, SiCN, SiOC, SiOCN, or the like. The dielectric layer 188 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

In some embodiments, the back-side metal pads 190 are made of a conductive material including aluminum (Al), copper (Cu), tungsten (W), titanium (Ti), tantalum (Ta), titanium nitride (TiN), cobalt, tantalum nitride (TaN), nickel silicide (NiSi), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. The back-side metal pads 190 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable processes.

Although not specifically illustrated, conductive connectors may be formed. The conductive connectors may be ball grid array (BGA) connectors, solder balls, metal pillars, controlled collapse chip connection (C4) bumps, micro bumps, electroless nickel/electroless palladium/immersion gold technique (ENEPIG) formed bumps, or the like. The conductive connectors may include a conductive material including aluminum (Al), copper (Cu), tungsten (W), titanium (Ti), tantalum (Ta), titanium nitride (TiN), cobalt, tantalum nitride (TaN), nickel silicide (NiSi), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the conductive connectors are formed by initially forming a layer of solder through evaporation, electroplating, printing, solder transfer, ball placement, or the like. Once a layer of solder has been formed on the structure, a reflow may be performed in order to shape the material into desired bump shapes. In another embodiments, the conductive connectors include metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

To sum up, a semiconductor device 200 includes a device layer 104, a front-side interconnect structure 130, a back-side interconnect structure 180, a bevel oxide 140, and an oxide layer 150 is provided. The front-side interconnect structure 130 is formed over the front-side surface of the device layer 104. The back-side interconnect structure 180 is formed over the back-side surface of the device layer 104. In other words, the device layer 104 is located between the front-side interconnect structure 130 and the back-side interconnect structure 180. Accordingly, the electrical signals on the back-side surface of the device layer 104 may be transferred to the elements formed on the front-side surface of the device layer 104 via the back-side interconnect structure 180 and the front-side interconnect structure 130.

The bevel oxide 140 covers the bevel region of the front-side interconnect structure 130. The oxide layer 150 covers the central region of the front-side interconnect structure 130. In some embodiments, the width of the bevel oxide 140 is less than the width of the oxide layer 150. In some embodiments, the bevel oxide 140 has a non-uniform thickness. For example, the bevel oxide 140 may have a maximum thickness 140T1 and a minimum thickness 140T2 different from the maximum thickness 140T1. In some embodiments, the oxide layer 150 may have a uniform thickness. For example, the oxide layer 150 may have substantially the same maximum thickness and minimum thickness denoted as 150T.

In some embodiments, the maximum thickness 140T1 of the bevel oxide 140 is greater than the maximum thickness 150T of the oxide layer 150. In some embodiments, the minimum thickness 140T2 of the bevel oxide 140 is substantially the same as the maximum thickness 150T of the oxide layer 150. In some embodiments, the maximum thickness 150T of the oxide layer 150 is in a range from about 200 nm to about 300 nm. The oxide layer 150 can improve thermal effects and possess good thermal stability due to its relatively small thickness. This also effectively reduces the overall thickness of the semiconductor device 200.

The bevel oxide 140 may provide protection on the bevel region of the semiconductor device 200. The bevel oxide 140 may also provide sufficient mechanical support for direct bonding with the carrier substrate 160. In some embodiments, no bubble is generated in the semiconductor device 200. The direct bonding between the carrier substrate 160 and the bevel oxide 140 reduces the thickness of the semiconductor device 200, saves manufacturing costs, and simplifies manufacturing processes because there is no layer wrapping the bevel oxide 140. Furthermore, due to the reduced thickness of the semiconductor device 200, thermal effects are improved, yield is increased, and the manufacturing processes are optimized.

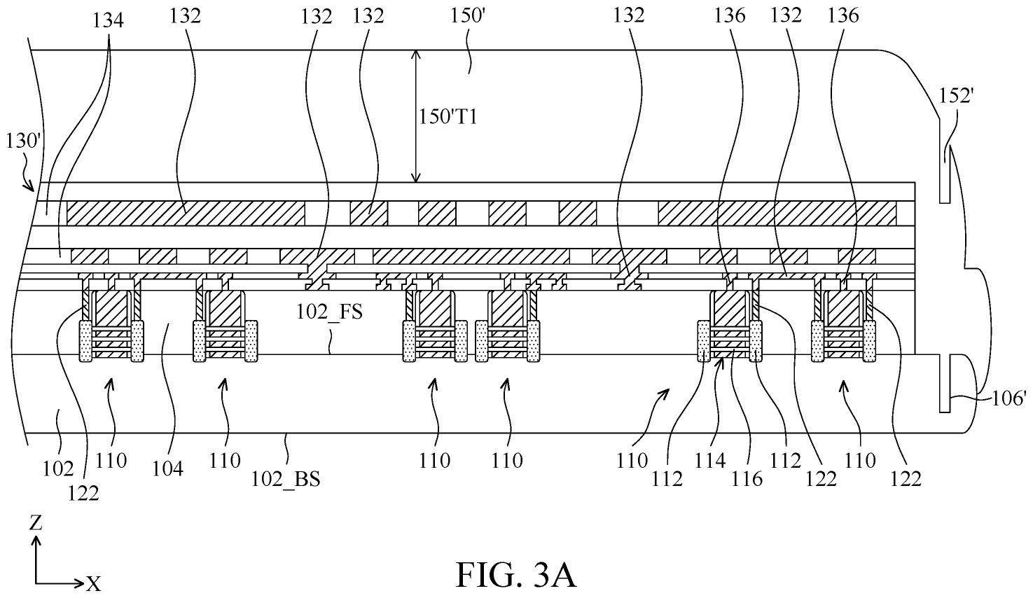

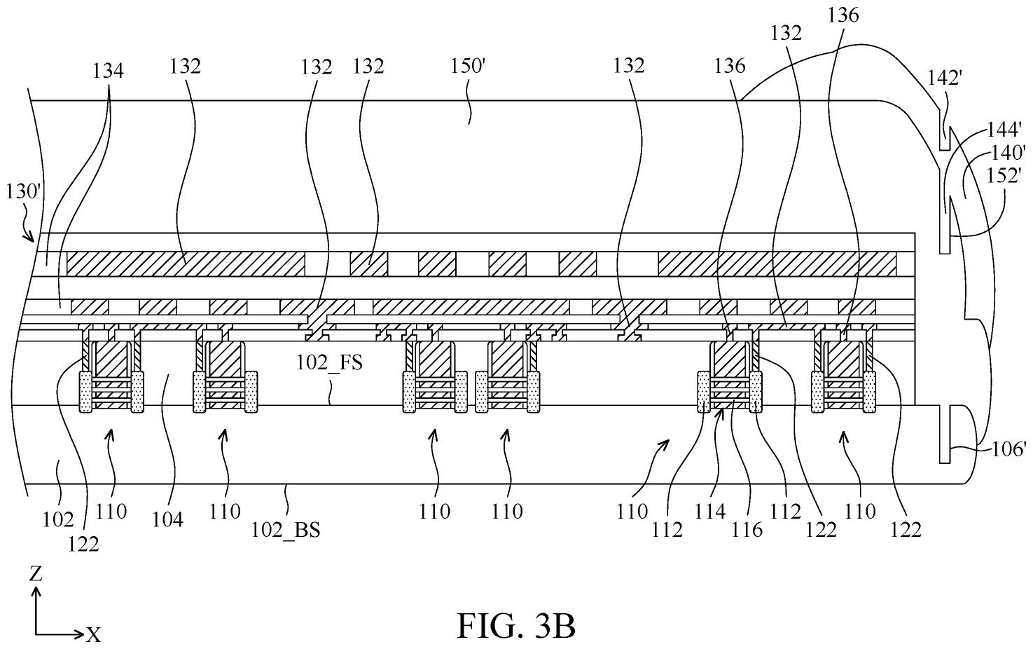

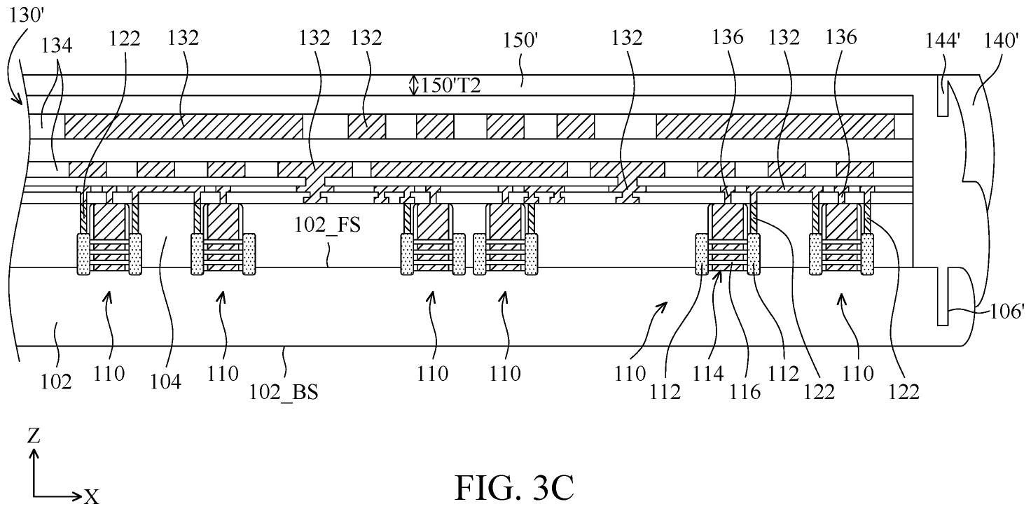

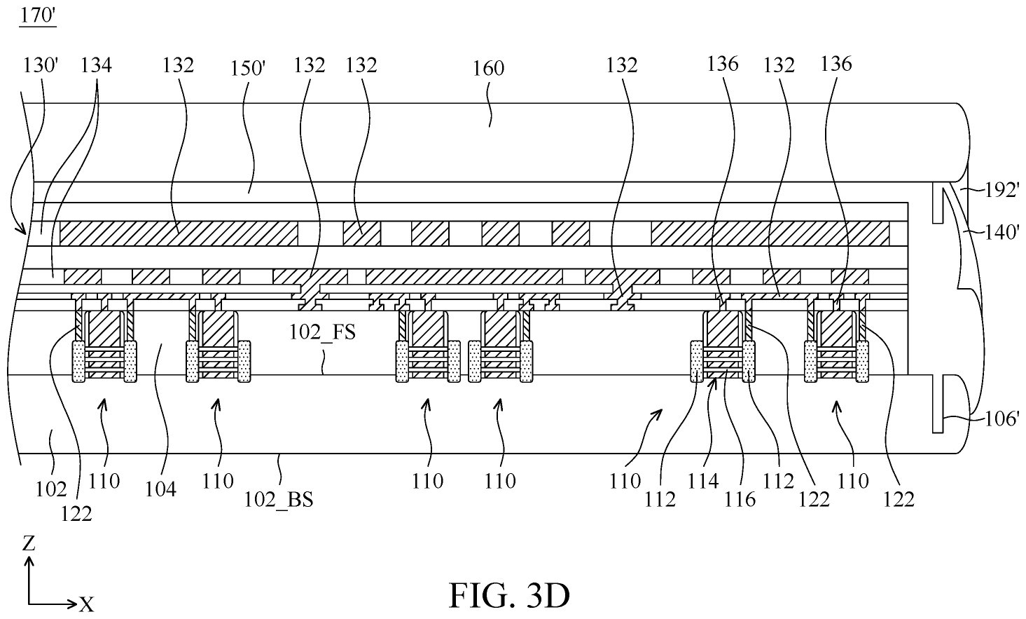

FIG. 3A to FIG. 3D illustrate cross-sectional views of forming an intermediate structure 170′ in accordance with some embodiments. The method embodiments illustrated in FIG. 2A to FIG. 2J and the method embodiments illustrated in FIG. 3A to FIG. 3D are performed in a different order. In addition, the shape of a device recessed portion 106′ illustrated in FIG. 3A to FIG. 3D is different from the shape of the device recessed portion 106 illustrated in FIG. 2A to FIG. 2J. The device recessed portion 106 is trapezoid-shaped, and the device recessed portion 106′ is rectangular, but the actual shape of the device recessed portion is not limited thereto. The actual shape of the device recessed portion may be affected by the manufacturing processes. Furthermore, the shape of a front-side interconnect structure 130′ illustrated in FIG. 3A to FIG. 3D is different from the shape of the front-side interconnect structure 130′ illustrated in FIG. 2A to FIG. 2J. The top surface of the front-side interconnect structure 130′ and the bottom surface of the front-side interconnect structure 130′ have substantially the same width.

An oxide layer 150′ is formed over the device substrate 102, the device layer 104, and the front-side interconnect structure 130, as shown in FIG. 3A in accordance with some embodiments. In some embodiments, the formation of the oxide layer 150′ includes filling the device recessed portion 106′ with the oxide layer 150′. The formation of the oxide layer 150′ is affected by the topography of the underlying structures, and thus an oxide layer recessed portion 152′ is formed in the oxide layer 150′. In some embodiments, the formation of the oxide layer 150′ includes depositing the oxide layer 150 until the thickness 150′T1 of the portion of the oxide layer 150′ that is directly over the front-side interconnect structure 130 is about 1000 nm.

Then, a bevel oxide 140′ is formed over the edge portion of the oxide layer 150′, the edge portion of the front-side interconnect structure 130′, the edge portion of the device substrate 102, as shown in FIG. 3B in accordance with some embodiments. In some embodiments, the formation of the bevel oxide 140′ includes filling the oxide layer recessed portion 152′ with the bevel oxide 140′. In other words, the bevel oxide 140′ includes a bevel oxide extending portion 144′ extending into the oxide layer recessed portion 152′. The formation of the bevel oxide 140′ is affected by the topography of the underlying structures, and thus a bevel oxide recessed portion 142′ is formed in the bevel oxide 140′. The device recessed portion 106′ at least partially overlaps the oxide layer recessed portion 152′ and the bevel oxide recessed portion 142′ vertically, and the oxide layer recessed portion 152′ is between the device recessed portion 106′ and the bevel oxide recessed portion 142′. In some embodiments, the thickness of the bevel oxide recessed portion 142′ is different from the thickness of the oxide layer recessed portion 152′.

Then, the oxide layer 150′ and the bevel oxide 140′ are polished until the top surface of the oxide layer 150′ is substantially level with the top surface of the bevel oxide 140′, as shown in FIG. 3C in accordance with some embodiments. The polishing of the oxide layer 150′ and the bevel oxide 140′ reduces the thickness of the oxide layer 150′ and the thickness of the bevel oxide 140′ along the Z-direction. In some embodiments, the polishing of the oxide layer 150′ and the bevel oxide 140′ includes exposing the bevel oxide extending portion 144′. In some embodiments, the polishing of the oxide layer 150′ includes polishing the oxide layer 150′ until the thickness 150′T2 of the portion that is directly over the front-side interconnect structure 130 is in a range from about 200 nm to about 300 nm.

After the oxide layer 150′ and the bevel oxide 140′ are polished to a desirable thickness, a carrier substrate 160 is then attached to the oxide layer 150′ and the bevel oxide 140′ to form the intermediate structure 170′, as shown in FIG. 3D in accordance with some embodiments. Furthermore, a seal 192′ may also be added to the intermediate structure 170′. In some embodiments, the seal 192′ is formed between the carrier substrate 160 and the bevel oxide 140′ to enhance the bonding therebetween. It should be noted that, the aforementioned processes such as a thinning process, a trimming process, or the like, may be further performed to the intermediate structure 170′ to obtain a semiconductor device.

As described above, a semiconductor device and method for forming the same are provided. The semiconductor device may include a device layer, a front-side interconnect structure, a back-side interconnect structure, a bevel oxide, and an oxide layer. The front-side interconnect structure is formed over the front-side surface of the device layer. The back-side interconnect structure is formed over the back-side surface of the device layer. In other words, the device layer is located between the front-side interconnect structure and the back-side interconnect structure. Accordingly, the electrical signals on the back-side surface of the device layer may be transferred to the elements formed on the front-side surface of the device layer via the back-side interconnect structure and the front-side interconnect structure. The bevel oxide covers the bevel region of the front-side interconnect structure. The oxide layer covers the central region of the front-side interconnect structure.

The bevel oxide may provide protection on the bevel region of the semiconductor device. The bevel oxide may also provide sufficient mechanical support for direct bonding with the carrier substrate. The oxide layer can improve thermal effects and possess good thermal stability due to its relatively small thickness. This also effectively reduces the overall thickness of the semiconductor device. In some embodiments, no bubble is generated in the semiconductor device. The direct bonding between the carrier substrate and the bevel oxide reduces the thickness of the semiconductor device, saves manufacturing costs, and simplifies manufacturing processes because there is no layer wrapping the bevel oxide. Furthermore, due to the reduced thickness of the semiconductor device, thermal effects are improved, yield is increased, and the manufacturing processes are optimized.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a method for forming a semiconductor device is provided. The method includes forming a device layer over a device substrate and forming a front-side interconnect structure over the device layer. The method also includes forming a bevel oxide over an edge portion of the device substrate, an edge portion of the device layer, and an edge portion of the front-side interconnect structure. The method further includes forming an oxide layer over the device layer, the front-side interconnect structure, and the bevel oxide, polishing the bevel oxide and the oxide layer until a top surface of the bevel oxide is substantially level with a top surface of the oxide layer, and attaching a carrier substrate to the bevel oxide and the oxide layer.

In some embodiments, the method further includes flipping over the device substrate and thinning the device substrate. In some embodiments, the method further includes forming a back-side interconnect structure over the device layer, wherein the back-side interconnect structures includes a plurality of back-side vias, a plurality of back-side through vias, and a plurality of back-side metal pads. In some embodiments, the bevel oxide and the oxide layer are polished by performing a chemical mechanical polishing process, and a polishing rate of the oxide layer is different from a polishing rate of the bevel oxide during the chemical mechanical polishing process.

In some embodiments, the bevel oxide has a bevel oxide recessed portion filled with the oxide layer before the bevel oxide and the oxide layer are polished. In some embodiments, the oxide layer has an oxide layer recessed portion vertically overlapping the bevel oxide recessed portion before the bevel oxide and the oxide layer are polished. In some embodiments, the oxide layer has an oxide layer extending portion extending into the bevel oxide recessed portion, and the extending portion is exposed after the bevel oxide and the oxide layer are polished.

In some embodiments, the method further includes trimming the bevel oxide, the front-side interconnect structure, and the device substrate before the carrier substrate is attached to the bevel oxide and the oxide layer. In some embodiments, a width of a top surface of the device substrate is less than a width of a bottom surface of the device substrate after the bevel oxide, the front-side interconnect structure, and the device substrate are trimmed. In some embodiments, a width of a top surface of the front-side interconnect structure is different from a width of a bottom surface of the front-side interconnect structure.

According to some embodiments, a method for forming a semiconductor device is provided. The method includes forming transistors over a front-side surface of a device substrate and forming a first interconnect structure over the transistors. The method also includes forming an oxide layer and a bevel oxide over the device substrate and partially removing the oxide layer and the bevel oxide until a top surface of the oxide layer is substantially level with a top surface of the bevel oxide. The method further includes attaching a carrier substrate to the oxide layer and the bevel oxide and polishing a back-side surface of the device substrate. The device substrate has a device recessed portion formed on the front-side surface.

In some embodiments, the oxide layer has an oxide layer recessed portion, the bevel oxide has a bevel oxide recessed portion, and the device recessed portion, the oxide layer recessed portion, and the bevel oxide recessed portion at least partially overlap each other vertically. In some embodiments, the bevel oxide recessed portion is between the oxide layer recessed portion and the device recessed portion. In some embodiments, the oxide layer recessed portion is between the bevel oxide recessed portion and the device recessed portion. In some embodiments, the method further includes forming a seal between the carrier substrate and the bevel oxide.

According to some embodiments a semiconductor device is provided. The semiconductor device includes a device layer, a front-side interconnect structure, a back-side interconnect structure, an oxide layer, and a bevel oxide. The front-side interconnect structure is formed over a front-side surface of the device layer. The back-side interconnect structure is formed over a back-side surface of the device layer. The oxide layer covers a central region of the front-side interconnect structure. The bevel oxide covers a bevel region of the front-side interconnect structure. The oxide layer and the bevel oxide are made of different dielectric materials.

In some embodiments, a width of the bevel oxide is less than a width of the oxide layer. In some embodiments, a maximum thickness of the bevel oxide is greater than a maximum thickness of the oxide layer. In some embodiments, a minimum thickness of the bevel oxide is substantially the same as the maximum thickness of the oxide layer. In some embodiments, a maximum thickness of the oxide layer is in a range from about 200 nm to about 300 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a device layer over a device substrate;
forming a front-side interconnect structure over the device layer;
forming a bevel oxide over an edge portion of the device substrate, an edge portion of the device layer, and an edge portion of the front-side interconnect structure;
forming an oxide layer over the device layer, the front-side interconnect structure, and the bevel oxide;
polishing the bevel oxide and the oxide layer until a top surface of the bevel oxide is substantially level with a top surface of the oxide layer; and
attaching a carrier substrate to the bevel oxide and the oxide layer.

2. The method as claimed in claim 1, further comprising flipping over the device substrate and thinning the device substrate.

3. The method as claimed in claim 2, further comprising forming a back-side interconnect structure over the device layer, wherein the back-side interconnect structure comprises a plurality of back-side vias, a plurality of back-side through vias, and a plurality of back-side metal pads.

4. The method as claimed in claim 1, wherein the bevel oxide and the oxide layer are polished by performing a chemical mechanical polishing process, and a polishing rate of the oxide layer is different from a polishing rate of the bevel oxide during the chemical mechanical polishing process.

5. The method as claimed in claim 1, wherein the bevel oxide has a bevel oxide recessed portion filled with the oxide layer before the bevel oxide and the oxide layer are polished.

6. The method as claimed in claim 5, wherein the oxide layer has an oxide layer recessed portion vertically overlapping the bevel oxide recessed portion before the bevel oxide and the oxide layer are polished.

7. The method as claimed in claim 5, wherein the oxide layer has an oxide layer extending portion extending into the bevel oxide recessed portion, and the oxide layer extending portion is exposed after the bevel oxide and the oxide layer are polished.

8. The method as claimed in claim 1, further comprising trimming the bevel oxide, the front-side interconnect structure, and the device substrate before the carrier substrate is attached to the bevel oxide and the oxide layer.

9. The method as claimed in claim 8, wherein a width of a top surface of the device substrate is less than a width of a bottom surface of the device substrate after the bevel oxide, the front-side interconnect structure, and the device substrate are trimmed.

10. The method as claimed in claim 1, wherein a width of a top surface of the front-side interconnect structure is different from a width of a bottom surface of the front-side interconnect structure.

11. A method for forming a semiconductor device, comprising:
forming transistors over a front-side surface of a device substrate;
forming a first interconnect structure over the transistors;
forming an oxide layer and a bevel oxide over the device substrate;
partially removing the oxide layer and the bevel oxide until a top surface of the oxide layer is substantially level with a top surface of the bevel oxide;
attaching a carrier substrate to the oxide layer and the bevel oxide; and
polishing a back-side surface of the device substrate,
wherein the device substrate has a device recessed portion formed on the front-side surface.

12. The method as claimed in claim 11, wherein the oxide layer has an oxide layer recessed portion, the bevel oxide has a bevel oxide recessed portion, and the device recessed portion, the oxide layer recessed portion, and the bevel oxide recessed portion at least partially overlap each other vertically.

13. The method as claimed in claim 12, wherein the bevel oxide recessed portion is between the oxide layer recessed portion and the device recessed portion.

14. The method as claimed in claim 12, wherein the oxide layer recessed portion is between the bevel oxide recessed portion and the device recessed portion.

15. The method as claimed in claim 11, further comprising forming a seal between the carrier substrate and the bevel oxide.

16. A semiconductor device, comprising:
a device layer;
a front-side interconnect structure over a front-side surface of the device layer;
a back-side interconnect structure over a back-side surface of the device layer;
an oxide layer covering a central region of the front-side interconnect structure; and
a bevel oxide covering a bevel region of the front-side interconnect structure,
wherein the oxide layer and the bevel oxide are made of different dielectric materials.

17. The semiconductor device as claimed in claim 16, wherein a width of the bevel oxide is less than a width of the oxide layer.

18. The semiconductor device as claimed in claim 16, wherein a maximum thickness of the bevel oxide is greater than a maximum thickness of the oxide layer.

19. The semiconductor device as claimed in claim 18, wherein a minimum thickness of the bevel oxide is substantially the same as the maximum thickness of the oxide layer.

20. The semiconductor device as claimed in claim 16, wherein a maximum thickness of the oxide layer is in a range from about 200 nm to about 300 nm.
